(19) United States
(12) Patent Application Publication
(10) Pub. No.: US 2023/0171853 A1
(43) Pub. Date: Jun. 1, 2023

(54) HEATING DEVICE AND SUBSTRATE PROCESSING APPARATUS COMPRISING THE SAME

(71) Applicant: SEMES CO., LTD., Chungcheongnam-do (KR)

(72) Inventors: Min Hee CHO, Gyeonggi-do (KR); Won Young KANG, Gyeonggi-do (KR); Jun Ho SONG, Gyeonggi-do (KR)

(21) Appl. No.: 17/865,976

(22) Filed: Jul. 15, 2022

(30) Foreign Application Priority Data
Nov. 30, 2021 (KR) 10-2021-0168386

(51) Int. Cl. H05B 3/00; G01K 13/02; H05B 3/40; H05B 3/03

(52) U.S. Cl. CPC H05B 3/0004; G01K 13/02; H05B 3/03; H05B 3/40

(57) ABSTRACT

A heating device capable of heating a processing liquid stably and efficiently is provided. The heating device comprises a first unit heater including a first flow path, a second unit heater including a second flow path, and a first tube connecting the first unit heater and the second unit heater, wherein a processing liquid flows through the first flow path, the first tube, and the second flow path, and is heated by the first unit heater and the second unit heater, wherein the first unit heater comprises a first pipe extending along a first direction and including the first flow path formed therein along the first direction, a first input terminal formed on a surface of the first pipe and extending in the first direction, a first output terminal formed on a surface of the first pipe, extending in the first direction, and spaced apart from the first input terminal, a plurality of first heating wires spaced apart from each other, formed on a surface of the first pipe, and connecting the first input terminal and the first output terminal.

This application claims the benefit of Korean Patent Application No. 10-2021- 0168386, filed on Nov. 30, 2021, in the Korean Intellectual Property Office, the disclosure of which is incorporated herein by reference in its entirety.

### BACKGROUND

### 1. Field

The present invention relates to a heating device and a substrate processing apparatus including the same.

### 2. Description of the Related Art

The processing liquid is heated to a target temperature by using a heating device, and the processing liquid is supplied to the substrate. A conventional heating device includes a water tank, in which a processing liquid is stored, and a heat source in contact with the processing liquid to heat the processing liquid.

### SUMMARY

Meanwhile, the conventional heat source includes a heating element, a body (metal material) that transmits heat of the heating element, and a cover (e.g., fluororesin material) that surrounds the body and contacts the processing liquid.

Since the heat generated from the heating element is transferred to the processing liquid through the body and the cover, there are many heat transfer steps, so the heating efficiency is lowered. In addition, the high-temperature heat generated from the heating element may be transferred to the plastic cover to cause damage to the cover. The processing liquid may enter the inside through the damaged cover, causing the heating device to malfunction.

Alternatively, the cover made of a fluororesin has absorption and permeation properties, thereby allowing particulate migration from the heating element. Therefore, the metal particles of the heating element may contaminate the processing liquid.

In addition, the processing liquid is heated by a heat source while being immersed in the water tank, and the heated processing liquid is transferred out of the water tank. However, depending on the design of the internal space of the water tank, some of the processing liquid may not be transferred out of the water tank and may remain. That is, some of the processing liquid may stagnate or swirl in the water tank. The stagnant processing liquid may be excessively heated by the heat source.

An object of the present invention is to provide a heating device capable of heating a processing liquid stably and efficiently.

Another object of the present invention is to provide a substrate processing apparatus including the heating device.

The objects of the present invention are not limited to the objects mentioned above, and other objects not mentioned will be clearly understood by those skilled in the art from the following description.

One aspect of the heating device of the present invention for achieving the above object comprises a first unit heater including a first flow path, a second unit heater including a second flow path, and a first tube connecting the first unit heater and the second unit heater, wherein a processing liquid flows through the first flow path, the first tube, and the second flow path, and is heated by the first unit heater and the second unit heater, wherein the first unit heater comprises a first pipe extending along a first direction and including the first flow path formed therein along the first direction, a first input terminal formed on a surface of the first pipe and extending in the first direction, a first output terminal formed on a surface of the first pipe, extending in the first direction, and spaced apart from the first input terminal, a plurality of first heating wires spaced apart from each other, formed on a surface of the first pipe, and connecting the first input terminal and the first output terminal.

Another aspect of the heating device of the present invention for achieving the above object comprises a pipe having a flow path, through which a processing liquid flows, therein and extending in one direction, an input terminal formed on a surface of the pipe and extending along the one direction, an output terminal formed on a surface of the pipe, extending along the one direction, and spaced apart from the input terminal, and a plurality of heating wires spaced apart from each other, formed on a surface of the pipe, and connecting the input terminal and the output terminal.

One aspect of the substrate processing apparatus of the present invention for achieving the above other object comprises a first tank for storing a processing liquid, and a first circulation path for circulating the processing liquid discharged from the first tank, wherein a heating unit for heating the circulated processing liquid is installed on the first circulation path, wherein the heating unit includes a first unit heater, a second unit heater, and a third unit heater connected in series, wherein the first unit heater includes a first flow path, the second unit heater includes a second flow path, and the third unit heater includes a third flow path, wherein the circulated processing liquid flows through the first flow path, the second flow path, and the third flow path in order, and is heated by the first unit heater to the third unit heater, wherein each of the first to third unit heaters comprises a pipe having a flow path, through which a processing liquid flows, therein, and extending in one direction, an input terminal formed on a surface of the pipe and extending along the one direction, an output terminal formed on a surface of the pipe, extending along the one direction, and spaced apart from the input terminal, and a plurality of heating wires spaced apart from each other, formed on a surface of the pipe, and connecting the input terminal and the output terminal.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view for describing a heating device according to some embodiments of the present invention;

FIG. 2 is an enlarged view of region II in order to describe the relationship between the input terminal, the output terminal, and the plurality of heating wires illustrated in FIG. 1;

FIG. 3 is a diagram illustrating a region III in order to describe a relationship between a plurality of heating wires and a temperature sensor illustrated in FIG. 1;

FIG. 4 is a view for describing the operation of the heating device according to some embodiments of the present invention;

FIG. 5 is a view for describing a heating device according to the first embodiment of the present invention;

FIG. 6 is a view for describing a heating device according to a second embodiment of the present invention;

FIG. 7 is a view for describing a heating device according to a third embodiment of the present invention;

FIG. 8 is a view for describing a modular form of the heating device shown in FIG. 7;

FIG. 9 is a view for describing the support plate of FIG. 8;

FIG. 10 is a view for describing a heating device according to a third embodiment of the present invention;

FIG. 11 is a block diagram for describing a heating device according to a fourth embodiment of the present invention;

FIG. 12 is a block diagram for describing a heating device according to a fifth embodiment of the present invention; and

FIG. 13 is a view for describing a substrate processing apparatus according to some embodiments of the present invention.

### DETAILED DESCRIPTION

Hereinafter, preferred embodiments of the present disclosure will be described in detail with reference to the accompanying drawings. Advantages and features of the present disclosure and methods of achieving them will become apparent with reference to the embodiments described below in detail in conjunction with the accompanying drawings. However, the present disclosure is not limited to the embodiments described below, but may be implemented in various different forms, and these embodiments are provided only for making the description of the present disclosure complete and fully informing those skilled in the art to which the present disclosure pertains on the scope of the present disclosure, and the present disclosure is only defined by the scope of the claims. Like reference numerals refer to like elements throughout.

Spatially relative terms “below,” “beneath,” “lower,” “above,” and “upper” can be used to easily describe a correlation between an element or components and other elements or components. The spatially relative terms should be understood as terms including different orientations of the device during use or operation in addition to the orientation shown in the drawings. For example, when an element shown in the figures is turned over, an element described as “below” or “beneath” another element may be placed “above” the other element. Accordingly, the exemplary term “below” may include both directions below and above. The device may also be oriented in other orientations, and thus spatially relative terms may be interpreted according to orientation.

Although first, second, etc. are used to describe various elements, components, and/or sections, it should be understood that these elements, components, and/or sections are not limited by these terms. These terms are only used to distinguish one element, component, or section from another element, component, or section. Accordingly, the first element, the first component, or the first section mentioned below may be the second element, the second component, or the second section within the technical spirit of the present disclosure.

Hereinafter, embodiments of the present disclosure will be described in detail with reference to the accompanying drawings, and in the description with reference to the accompanying drawings, the same or corresponding components are given the same reference numbers, regardless of reference numerals in drawings, and an overlapped description therewith will be omitted.

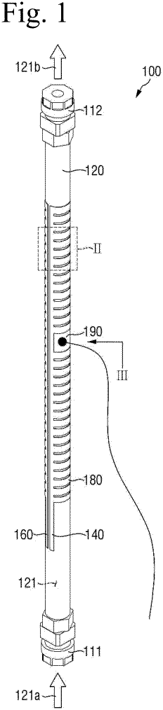

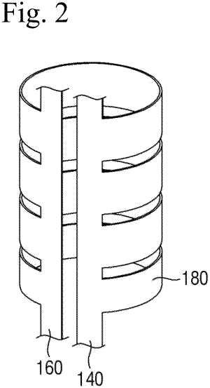

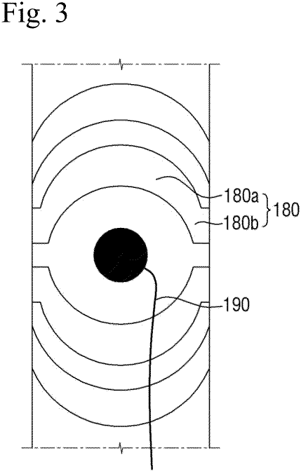

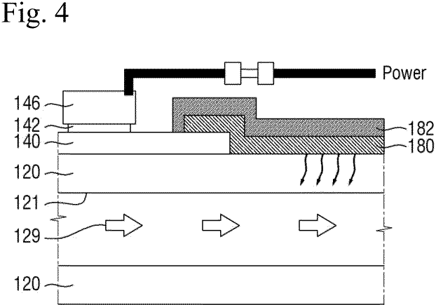

FIG. 1 is a perspective view for describing a heating device according to some embodiments of the present invention. FIG. 2 is an enlarged view of region II in order to describe the relationship between the input terminal, the output terminal, and the plurality of heating wires illustrated in FIG. 1. FIG. 3 is a diagram illustrating a region III in order to describe a relationship between a plurality of heating wires and a temperature sensor illustrated in FIG. 1. FIG. 4 is a view for describing the operation of the heating device according to some embodiments of the present invention.

First, referring to FIG. 1, a unit heater 100 used in a heating device according to some embodiments of the present invention includes a pipe 120, an input terminal 140, an output terminal 160, a plurality of heating wires 180, a temperature sensor 190 and the like.

The pipe 120 extends in one direction, and a flow path 121, through which the processing liquid flows, is formed therein. The pipe 120 may be made of, for example, quartz.

A first connection fitting 111 is installed on one side of the pipe 120, and a second connection fitting 112 is installed on the other side of the pipe 120. The first connection fitting 111 and the second connection fitting 112 may be made of a fluororesin having excellent chemical resistance, heat resistance and electrical insulation, but is not limited thereto. The fluororesin may be, for example, Poly Fluoro Alkoxy (PFA), Poly Tetra Fluoro Ethylene (PTFE), Ethylene Tetra Fluoro Ethylene (ETPE), or the like, but is not limited thereto.

The input terminal 140 is formed on the surface of the pipe 120 and extends long along one direction (i.e., the extending direction of the pipe 120). The output terminal 160 is also formed on the surface of the pipe 120 and extends long along the one direction (i.e., the extending direction of the pipe 120). The input terminal 140 and the output terminal 160 are spaced apart from each other and arranged side by side. The input terminal 140 and the output terminal 160 may be a conductor (e.g., metal), but is not limited thereto.

A plurality of heating wires 180 are formed on the surface of the pipe 120, and connect the input terminal 140 and the output terminal 160. The heating wire 180 may be a resistor. The heating wire 180 generates heat by the power supply provided through the input terminal 140. That is, current is supplied through the input terminal 140, and the current flows through the heating wire 180 to the output terminal 160. The degree of heat generated by the heating wire 180 may vary according to an output size (e.g., amount of current) of the power supply. The heating wire 180 may be formed on the surface of the pipe 120 by a printing method, but is not limited thereto.

In addition, as shown in FIG. 2, the plurality of heating wires 180 are arranged to be spaced apart from each other in one direction (in the vertical direction in FIG. 2). The heating wire 180 is branched from one side (e.g., the right side) of the input terminal 140 and is connected to one side (e.g., the left side) of the output terminal 160 again after extending along the surface of the pipe 120. As shown, the heating wire 180 may have a ring shape connecting the input terminal 140 and the output terminal 160.

Here, referring to FIGS. 1 and 3, the temperature sensor 190 is attached to the surface of the pipe 120 to sense the temperature of the pipe 120. The temperature sensor 190 may be, for example, a thermocouple. The thermocouple is made of, for example, two metal wires, and can sense a temperature in a variety of ranges depending on the type of metal wire.

The temperature sensor 190 may be spaced apart from the plurality of heating wires 180 without contacting the plurality of heating wires 180. As shown, some of the plurality of heating wires 180 comprise a first region 180b connected to the input terminal 140 and/or the output terminal 160 and a second region 180a connected to the first region 180b. As illustrated, the second region 180a may be a curved region. A space, in which the temperature sensor 190 is attached, is provided between the second regions 180a of the two heating wires 180 facing each other. Based on the temperature sensed by the temperature sensor 190, the output of power supply supplied to the input terminal 140 may be adjusted.

Referring to FIG. 4, a flow path 121, through which a processing liquid flows, is formed inside the pipe 120. An input terminal 140 and an output terminal (not shown) are formed on the surface of the pipe 120. An adhesive material 142 (e.g., Ag sintering) may be located on the input terminal 140, and a terminal block 146 for supplying power supply may be installed on the adhesive material 142.

A plurality of heating wires 180 are formed to connect the input terminal 140 and the output terminal. As shown, some of the heating wires 180 may be conformally formed along the side and upper surfaces of the input terminal 140. An insulating film 182 is formed on the heating wire 180 so that the heating wire 180 is not exposed to the outside.

Referring to FIGS. 1 and 4, in the unit heater 100 according to some embodiments of the present invention, a processing liquid is heated in an inline heating method. Specifically, the processing liquid is supplied from one side of the pipe 120 (i.e., through the first connection fitting 111) to the flow path 121 in the pipe 120 (see reference numeral 121a). While the processing liquid flows along the flow path 121 (see reference numeral 129), the processing liquid is heated by the heating wire 180. The heated processing liquid 129 flows to the other side of the pipe 120 (i.e., through the second connection fitting 112) (see reference numeral 121b).

As described above, since the processing liquid is heated in the in-line heating method, the processing liquid does not stagnate in the pipe 120. Therefore, a problem such as excessive heating of the stagnant processing liquid does not occur.

On the other hand, quartz used for the pipe 120 is chemically stable, so it is a preferred material in a high-purity wet process. The quartz pipe 120 is hardly damaged by the heat source. When the pipe 120 made of quartz is used, the process yield can be improved because the generation of particles is less compared to the case of using the resin-based pipe.

Also, even when particles are generated, since the processing liquid does not stagnate in the pipe 120, particles are not collected or accumulated in the pipe 120. Even if bubbles are generated in the pipe 120, the bubbles are naturally discharged out of the pipe 120 along with the flow of the processing liquid.

In addition, since the heating wire 180 is formed on the surface of the pipe 120, heat generated by the heating wire 180 is directly transferred to the processing liquid through the pipe 120. That is, since the heat transfer step is short, the processing liquid heating efficiency is high.

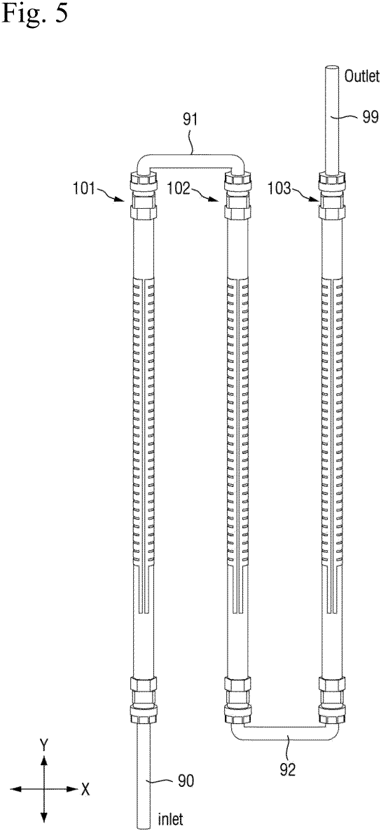

FIG. 5 is a view for describing a heating device according to the first embodiment of the present invention. For convenience of description, the points different from those described with reference to FIGS. 1 to 4 will be mainly described.

Referring to FIG. 5, the heating device according to the first embodiment of the present invention includes a plurality of unit heaters 101, 102, 103.

The plurality of unit heaters 101, 102, 103 are arranged side by side in the X direction. That is, the heating wire of the first unit heater 101 may face the heating wire of the second unit heater 102, and the heating wire of the second unit heater 102 may face the heating wire of the third unit heater 103. Each of the plurality of unit heaters 101, 102, and 103 may be substantially the same as the unit heater 100 described with reference to FIG. 1. A temperature sensor (not shown) may be installed in each of the plurality of unit heaters 101, 102, 103.

That is, the first unit heater 101 includes a first pipe extending along a first direction and having a first flow path installed therein, a first input terminal and a first output terminal formed on a surface of the first pipe and extending in the first direction, and a plurality of first heating wires formed on the surface of the first pipe and connecting the first input terminal and the first output terminal to each other.

Similarly, the second unit heater 102 includes a second pipe extending along the second direction and having a second flow path installed therein, a second input terminal and a second output terminal formed on the surface of the second pipe and extending in the second direction, and a plurality of second heating wires formed on the surface of the second pipe and connecting the second input terminal and the second output terminal to each other.

The third unit heater 103 includes a third pipe extending along the third direction and having a third flow path installed therein, and a third input terminal and a third output terminal formed on the surface of the third pipe and extending in the third direction, and a plurality of third heating wires formed on the surface of the third pipe and connecting the third input terminal and the third output terminal to each other.

As illustrated, all of the first direction, the second direction, and the third direction may be parallel to the Y direction.

The first unit heater 101 to the third unit heater 103 may be fluidly connected in series. That is, the inlet of the first unit heater 101 may be connected to the inlet tube 90, and the outlet of the first unit heater 101 and the inlet of the second unit heater 102 may be connected to each other through the first tube 91, the outlet of the second unit heater 102 and the inlet of the third unit heater 103 may be connected to each other through the second tube 92, and the outlet of the third unit heater 103 may be connected to the outlet tube 99.

The first tube 91 and the second tube 92 may have a U-shape. This is because the first unit heater 101 to the third unit heater 103 are arranged side by side along the X direction. Accordingly, in order to connect the outlet of the first unit heater 101 and the inlet of the second unit heater 102, the first tube 91 may have a U-shape. Similarly, in order to connect the outlet of the second unit heater 102 and the inlet of the third unit heater 103, the second tube 92 may have a U-shape.

The processing liquid is supplied to the first flow path through the inlet tube 90, and passes through the first flow path, the first tube 91, the second flow path, the second tube 92 and the third flow path, and discharged through the outlet tube 99. The processing liquid is heated by the first, second, and third heating wires while passing through the first, second, and third flow paths.

As described above, by using the plurality of unit heaters 101, 102, and 103, the temperature of the processing liquid may be increased to a preset temperature. In addition, since the plurality of unit heaters 101, 102, 103 are arranged side by side in the X direction, the heating device can be efficiently arranged.

Also, in the drawing, it is illustrated that the three unit heaters 101, 102, 103 are arranged in a line along the X direction (i.e., an I-shape), but the three unit heaters 101, 102, 103 may be arranged in a s L-shaped or a V-shape.

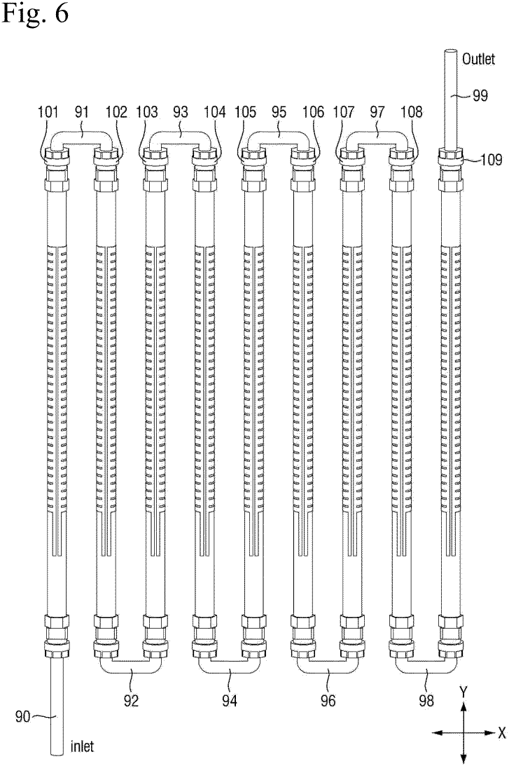

FIG. 6 is a view for describing a heating device according to a second embodiment of the present invention. For convenience of description, the points different from those described with reference to FIGS. 1 to 5 will be mainly described.

Referring to FIG. 6, the heating device according to the second embodiment of the present invention includes a plurality of unit heaters 101 to 109.

A plurality of unit heaters 101 to 109 are arranged side by side in the X direction. Each of the plurality of unit heaters 101 to 109 may be substantially the same as the unit heater 100 described with reference to FIG. 1. Each of the plurality of unit heaters 101 to 109 includes a flow path therein, and an input terminal, an output terminal, and a plurality of heating wires are installed on the surface of the pipe.

The plurality of unit heaters 101 to 109 may be fluidly connected in series. That is, the outlet of the nth unit heater (where n is a natural number greater than or equal to 1 and less than or equal to 8) and the inlet of the n+1th unit heater are connected through tubes 91 to 98. As shown, the tubes 91 to 98 may have a U-shape, but are not limited thereto. The inlet of the first unit heater 101 may be connected to the inlet tube 90, and the outlet of the ninth unit heater 109 may be connected to the outlet tube 99.

The processing liquid is introduced through the inlet tube 90, passes through each flow path of the plurality of unit heaters 101 to 109, and is discharged through the outlet tube 99. The processing liquid is heated by a plurality of heating wires while passing through the flow paths of the plurality of unit heaters 101 to 109.

In FIG. 6, it is described that nine unit heaters 101 to 109 are fluidly connected in series, but the present invention is not limited thereto. That is, less than 9 unit heaters may be used, or 10 or more unit heaters may be used.

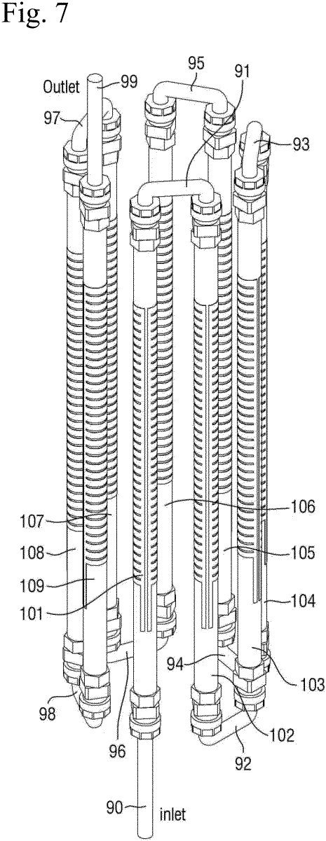

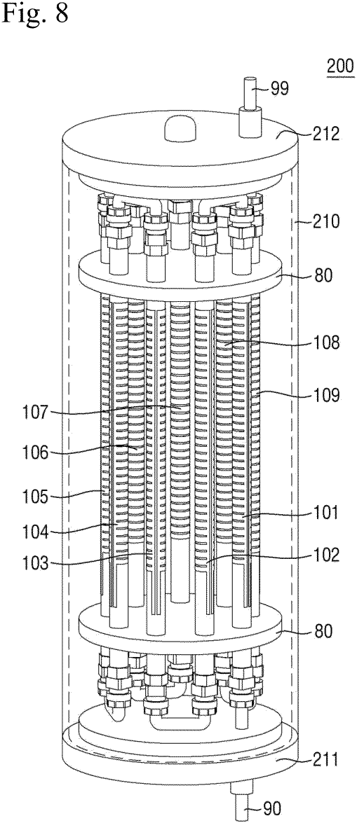

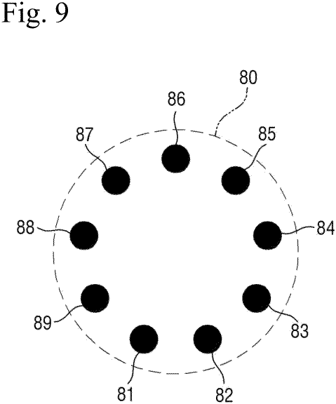

FGI. 7 is a view for describing a heating device according to a third embodiment of the present invention. FIG. 8 is a view for describing a modular form of the heating device shown in FIG. 7. FIG. 9 is a view for describing the support plate of FIG. 8. For convenience of description, the difference from the heating device described in FIG. 6 will be mainly described.

First, referring to FIG. 7, a plurality of unit heaters 101 to 109 may be arranged in parallel with each other, but may be arranged around a virtual circle.

The space, in which the plurality of unit heaters 101 to 109 are installed, can be minimized by arranging the plurality of unit heaters 101 to 109 around a virtual circle instead of side by side in the X direction as in FIG. 6.

Referring to FIGS. 7 to 9, the plurality of unit heaters 101 to 109 may be fixed by the support plate 80. The support plate 80 may have a circular shape, and a plurality of holes 81 to 89 for inserting and fixing each of the plurality of unit heaters 101 to 109 are installed in the support plate 80. By using the support plate 80, it is possible to maintain a constant distance between the plurality of unit heaters 101 to 109. In addition, it can prevent that a plurality of unit heaters 101 to 109 are shaken by an external impact, or the tubes 91 to 98, inlet tube 90, and outlet tube 99 connecting the unit heaters 101 to 109 are pulled out or damaged.

As shown, two support plates 80 are used to fix upper and lower sides of the plurality of unit heaters 101 to 109, but the present invention is not limited thereto. Only one support plate 80 may be used, or three or more may be used.

As described above, the plurality of unit heaters 101 to 109 fixed by the support plate 80 may be inserted/fixed in the cylindrical case 210. The inlet tube 90 may be installed to pass through the lower cover 211 of the case 210, and the outlet tube 99 may be installed to pass through the upper cover 212 of the case 210.

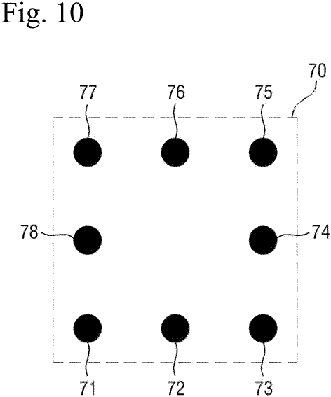

FIG. 10 is a view for describing a heating device according to a third embodiment of the present invention. For convenience of description, the points different from those described with reference to FIGS. 7 to 9 will be mainly described.

In the modular heating device described with reference to FIG. 8, a circular support plate 80 for fixing a plurality of unit heaters 101 to 109 is used, and a plurality of unit heaters 101 to 109 fixed to the support plate 80 are inserted/fixed in the cylindrical case 210.

On the other hand, referring to FIG. 10, a rectangular support plate 70 may be used to fix a plurality of unit heaters (e.g., 101 to 108). A plurality of holes 71 to 78 for fixing the plurality of unit heaters 101 to 108 may be installed in the support plate 70. Although not shown separately, the plurality of unit heaters 101 to 108 fixed by the rectangular support plate 70 may be inserted/fixed in the hexahedral case.

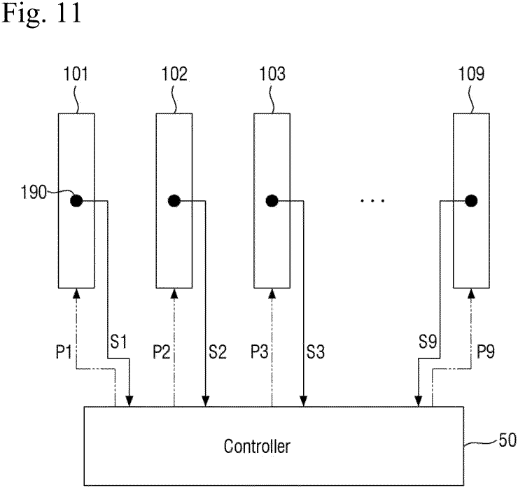

FIG. 11 is a block diagram for describing a heating device according to a fourth embodiment of the present invention.

Referring to FIG. 11, in the heating device according to the fourth embodiment of the present invention, a temperature sensor 190 is installed in each of the plurality of unit heaters 101 to 109.

The controller 50 receives the temperature signals S1 to S9 sensed from the temperature sensors 190 of the plurality of unit heaters 101 to 109. The power supplies P1 to P9 provided to each of the plurality of unit heaters 101 to 109 may be adjusted based on the sensed temperature signals S1 to S9. The on/off time of the power supplies P1 to P9 provided to each of the plurality of unit heaters 101 to 109 may be adjusted, or the size of the power supplies P1 to P9 may be controlled.

The size of the power supply P1 provided to one unit heater (e.g., 101) among the plurality of unit heaters 101 to 109 and the size of the power supply P9 provided to another unit heater (e.g., 109) can be controlled differently.

For example, the size of the power supplies P1 to P3 provided to the unit heaters (e.g., 101 to 103) located upstream among the plurality of unit heaters 101 to 109 may be relatively large, and the size of the power supplies P7 to P9 provided to the unit heaters (e.g., 107 to 109) located downstream may be relatively small. When the temperature of the processing liquid is sufficiently high while passing through the unit heaters 101 to 103 located upstream, it is not necessary to increase the size of the power supplies P7 to P9 supplied to the unit heaters 107 to 109 located downstream.

Conversely, the size of the power supplies P1 to P3 provided to the unit heaters (e.g., 101 to 103) located upstream among the plurality of unit heaters 101 to 109 may be relatively small, and the size of the power supplies P7 to P9 provided to the unit heaters (e.g., 107 to 109) located downstream may be relatively large. If the temperature of the processing liquid is not sufficiently high while passing through the unit heaters 101 to 103 located upstream, the size of the power supplies P7 to P9 supplied to the unit heaters 107 to 109 located downstream is increased, so that the temperature of the processing liquid is adjusted to the target value.

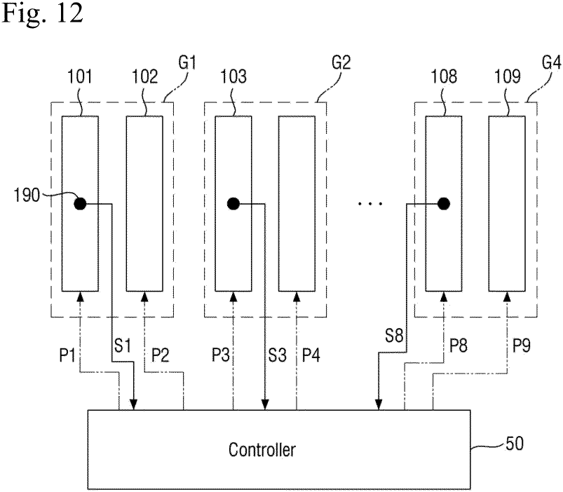

FIG. 12 is a block diagram for describing a heating device according to a fifth embodiment of the present invention. Points different from those described with reference to FIG. 11 will be mainly described.

Referring to FIG. 12, in the heating device according to the fifth embodiment of the present invention, a plurality of unit heaters 101 to 109 may be divided into several groups G1 to G4. As shown in FIG. 12, two or three unit heaters 101 to 109 may be grouped together. For example, the unit heaters 101 and 102 may be the first group G1, the unit heaters 103 and 104 may be the second group G2, and the unit heaters 105, 106 and 107 may be the third group G1 (not shown), and the unit heaters 108 and 109 may be the fourth group G4. Although it is described in FIG. 12 that two or three unit heaters 101 to 109 are bundled into one group, the present invention is not limited thereto.

The controller 50 receives the temperature signals S1, S3, and S8 from each of the plurality of groups G1 to G4. The power supplies P1 to P9 provided to each of the plurality of unit heaters 101 to 109 may be adjusted based on the sensed temperature signals S1, S3, and S8.

That is, a single temperature signal S1 is provided from a plurality of unit heaters 101 and 102 belonging to the first group G1, and power supplies P1, P2 provided to the unit heaters 101 and 102 belonging to the first group G1 can be controlled in the same way. Similarly, a single temperature signal S3 is provided from a plurality of unit heaters 103 and 104 belonging to the second group G2 and the power supplies P3 and P4 provided to the unit heaters 103 and 104 belonging to the second group G2 can be controlled in the same way.

Unlike the illustration, the controller 50 may receive the sensed temperature signals S1 to S9 from the temperature sensors 190 of the plurality of unit heaters 101 to 109, and control power supplies P1 and P2 provided to a plurality of unit heaters 101 and 102 belonging to each group (e.g., G1) in the same way based on the sensed temperature signals S1 to S9.

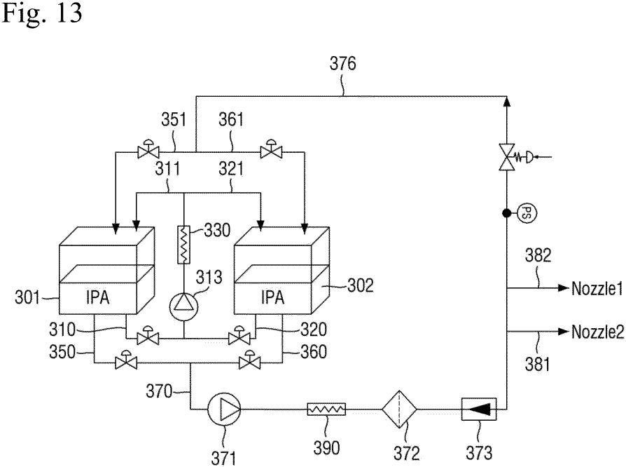

FIG. 13 is a view for describing a substrate processing apparatus according to some embodiments of the present invention. At least one of the heating devices described with reference to FIGS. 5 to 12 may be used as the heating devices 330 and 390 of FIG. 13.

Referring to FIG. 13, the substrate processing apparatus according to some exemplary embodiments may supply a processing liquid using dual tanks 301 and 302. In FIG. 13, the processing liquid stored in the dual tanks 301 and 302 may be IPA (Isopropyl alcohol) used in the drying process, but is not limited thereto. That is, various processing liquids used in a cleaning process, an etching process, and the like may be stored.

The processing liquid discharged from the first tank 301 or the second tank 302 may be re-supplied to the first tank 301 or the second tank 302 by moving along an internal circulation path. While moving along the internal circulation path, the processing liquid is heated by the heating device 330.

Specifically, the processing liquid discharged from the first tank 301 may be re-supplied to the first tank 301 through the pipe 310, the pump 313, the heating device 330, and the pipe 311. Alternatively, the processing liquid discharged from the second tank 302 may be re-supplied to the second tank 302 through the pipe 320, the pump 313, the heating device 330, and the pipe 321.

That is, the processing liquid discharged from the first tank 301 is heated by the heating device 330 and re-supplied to the first tank 301, and the processing liquid discharged from the second tank 302 is heated by the heating device 330 and re-supplied to the second tank 302. The heating device 330 is shared by the internal circulation path of the first tank 301 and the internal circulation path of the second tank 302. The processing liquid is heated by the heating device 330 to control the temperature of the processing liquid within a target range. Based on the temperature sensed by the temperature sensor installed in the heating device 330, the heating degree of the processing liquid is adjusted.

Alternatively, the processing liquid discharged from the second tank 302 may be supplied to the first tank 301 through the pipe 320, the pump 313, the heating device 330, and the pipe 311. The processing liquid discharged from the first tank 301 may be supplied to the second tank 302 through the pipe 310, the pump 313, the heating device 330, and the pipe 321.

Meanwhile, the processing liquid discharged from the first tank 301 or the second tank 302 may be re-supplied to the first tank 301 or the second tank 302 by moving along an external circulation path.

Specifically, the processing liquid discharged from the first tank 301 is provided to the merging pipe 370 through the pipe 350, and the processing liquid discharged from the second tank 302 is provided to the merging pipe 370 through the pipe 360. The processing liquid provided to the merging pipe 370 passes through the pump 371, the heating device 390, the filter 372, and the flow meter 373, and is then supplied to the nozzles in the chamber through the nozzle pipes 381 and 382.

Here, the processing liquid is heated by the heating device 390 to control the temperature of the processing liquid within a target range (i.e., an appropriate temperature range of the processing liquid to be used in the chamber). Based on the temperature sensed by the temperature sensor installed in the heating device 390, the heating degree of the processing liquid is adjusted.

Here, the processing liquid remaining without being supplied to the nozzle in the chamber is re-supplied to the first tank 301 through the pipes 376 and 351 or re-supplied to the second tank 302 through the pipes 376 and 361.

Although embodiments of the present invention have been described with reference to the above and the accompanying drawings, those skilled in the art, to which the present invention pertains, can understand that the present invention may be practiced in other specific forms without changing its technical spirit or essential features. Therefore, it should be understood that the embodiments described above are illustrative in all respects and not limiting.

What is claimed is:

1. A heating device comprising:
a first unit heater including a first flow path;
a second unit heater including a second flow path; and
a first tube connecting the first unit heater and the second unit heater,
wherein a processing liquid flows through the first flow path, the first tube, and the second flow path, and is heated by the first unit heater and the second unit heater,
wherein the first unit heater comprises,
a first pipe extending along a first direction and including the first flow path formed therein along the first direction,
a first input terminal formed on a surface of the first pipe and extending in the first direction,
a first output terminal formed on a surface of the first pipe, extending along the first direction, and spaced apart from the first input terminal,
a plurality of first heating wires spaced apart from each other, formed on a surface of the first pipe, and connecting the first input terminal and the first output terminal.

2. The heating device of claim 1, wherein the second unit heater comprises,
a second pipe extending in a second direction and including the second flow path formed therein along the second direction,
a second input terminal formed on a surface of the second pipe and extending along the second direction,
a second output terminal formed on a surface of the second pipe, extending along the second direction, and spaced apart from the second input terminal, and
a plurality of second heating wires spaced apart from each other, formed on a surface of the second pipe, and connecting the second input terminal and the second output terminal.

3. The heating device of claim 2, wherein the first unit heater and the second unit heater are arranged in parallel with each other, so that the plurality of first heating wires and the plurality of second heating wires face each other.

4. The heating device of claim 3, wherein the first tube has a U-shape to connect an outlet of the first pipe and an inlet of the second pipe.

5. The heating device of claim 2, wherein an output of a power supply supplied to the first input terminal and an output of a power supply supplied to the second input terminal are different from each other.

6. The heating device of claim 2, wherein the first unit heater further includes a temperature sensor attached to a surface of the first pipe and spaced apart from the plurality of first heating wires,
wherein an output of a power supply supplied to the first input terminal and the second input terminal is controlled according to a sensing result of a temperature sensor installed in the first unit heater.

7. The heating device of claim 1 further comprises,
a third unit heater including a third flow path; and
a second tube connecting the second unit heater and the third unit heater,
wherein the processing liquid flows through the first flow path, the first tube, the second flow path, the second tube, and the third flow path, and is heated by the first unit heater to the third unit heater,
wherein the first unit heater to the third unit heater are arranged in parallel with each other, and the first unit heater to the third unit heater are arranged around an imaginary circle.

8. The heating device of claim 1 further comprises,
a temperature sensor attached to a surface of the first pipe and spaced apart from the plurality of first heating wires.

9. The heating device of claim 8, wherein the temperature sensor comprises a thermocouple.

10. The heating device of claim 1, wherein a first connection fitting is installed on one side of the first pipe, and a second connection fitting is installed on the other side of the first pipe.

11. The heating device of claim 1, wherein the processing liquid is IPA, and the first pipe is a quartz pipe.

12. A heating device comprising:
a pipe having a flow path, through which a processing liquid flows, therein and extending in one direction;
an input terminal formed on a surface of the pipe and extending along the one direction;
an output terminal formed on a surface of the pipe, extending along the one direction, and spaced apart from the input terminal; and
a plurality of heating wires spaced apart from each other, formed on a surface of the pipe, and connecting the input terminal and the output terminal.

13. The heating device of claim 12 further comprises,
a temperature sensor attached to a surface of the pipe, and spaced apart from the plurality of heating wires.

14. The heating device of claim 13, wherein the temperature sensor comprises a thermocouple.

15. The heating device of claim 12, wherein a first connection fitting is installed on one side of the pipe, and a second connection fitting is installed on the other side of the pipe.

16. The heating device of claim 12 further comprises,
an insulating film formed on the plurality of heating wires.

17. An apparatus for processing a substrate comprising:
a first tank for storing a processing liquid; and
a first circulation path for circulating the processing liquid discharged from the first tank,
wherein a heating unit for heating the circulated processing liquid is installed on the first circulation path,
wherein the heating unit includes a first unit heater, a second unit heater, and a third unit heater connected in series,
wherein the first unit heater includes a first flow path, the second unit heater includes a second flow path, and the third unit heater includes a third flow path,
wherein the circulated processing liquid flows through the first flow path, the second flow path, and the third flow path in order, and is heated by the first unit heater to the third unit heater,
wherein each of the first to third unit heaters comprises,
a pipe having a flow path, through which a processing liquid flows, therein, and extending in one direction,
an input terminal formed on a surface of the pipe and extending along the one direction,
an output terminal formed on a surface of the pipe, extending along the one direction, and spaced apart from the input terminal, and
a plurality of heating wires spaced apart from each other, formed on a surface of the pipe, and connecting the input terminal and the output terminal.

18. The apparatus of claim 17, wherein the first to third unit heaters are arranged in parallel with each other, and the first to third unit heaters are arranged around an imaginary circle.

19. The apparatus of claim 17 further comprises,
a second tank for storing the processing liquid and separated from the first tank; and
a second circulation path for circulating the processing liquid discharged from the second tank,
wherein the first circulation path and the second circulation path share the heating unit.

20. The apparatus of claim 17 further comprises,
a temperature sensor attached to a surface of the pipe, and spaced apart from the plurality of heating wires.
